(19) United States
(12) Patent Application Publication
(10) Pub. No.: US 2026/0194612 A1
(43) Pub. Date: Jul. 9, 2026

(54) MULTIPLEXED CONTRAST MAGNETIC RESONANCE IMAGING

(71) Applicant: Northwestern University, Evanston, IL (US)

(72) Inventor: Mohammed Elbaz, Evanston, IL (US)

(21) Appl. No.: 19/444,610

(22) Filed: Jan. 9, 2026

Related U.S. Application Data
(60) Provisional application No. 63/743,570, filed on Jan. 9, 2025.

(51) Int. Cl. G01R 33/56; G06T 5/40; G06T 5/50; G06T 5/94

(52) U.S. Cl. CPC G01R 33/5608; G06T 5/40; G06T 5/50; G06T 5/94; G06T 2207/10088; G06T 2207/20076; G06T 2207/20224

(57) ABSTRACT

Multiplexed contrast magnetic resonance imaging (MRI) includes generating an output image from an input image, where the output image has a different contrast weighting than the input image. The contrast weighting of the output image can differ from the contrast weighting of the input image by suppressing image intensity values associated with a tissue, such as blood, that is contained in a calibration region of the input image. The input image is encoded into a spectral space in which image data associated with the tissue to be suppressed can be separated from other image data. The spectral encoding is facilitated using spectral profiles of the input image and calibration region. The calibration spectral profile is used to define spectral ranges that enable separation of the image data into different cumulative maps that can be selectively combined to generate the output image.

### CROSS-REFERENCE TO RELATED APPLICATIONS

This application claims the benefit of U.S. Provisional Patent Application Ser. No. 63/743,570, filed on Jan. 9, 2025, and entitled “MULTIPLEXED CONTRAST MAGNETIC RESONANCE IMAGING,” which is herein incorporated by reference in its entirety.

### BACKGROUND

Magnetic resonance angiography is typically performed using bright-blood techniques, with late gadolinium enhancement (LGE) MRI as a prominent example used to assess fibrosis in the left atrium (LA) for atrial fibrillation diagnosis, treatment planning, and guiding ablation interventions. However, bright-blood magnetic resonance imaging (MRI) often lacks sufficient contrast between vessel walls and blood pools, reducing visibility of fine details like scarring. Dark-blood MRI improves this contrast by suppressing blood signal, but it requires additional scans, leading to increased scan time, patient discomfort, and technical challenges, especially in areas with rapid motion or thin structures. These issues lower signal-to-noise ratio (SNR) and limit clinical utility.

### SUMMARY OF THE DISCLOSURE

It is an aspect of the present disclosure to provide a method for multiplexed contrast magnetic resonance imaging (MRI). The method includes accessing a first image acquired with an MRI system from a subject, where the first image has a first contrast weighting. A region-of-interest in the first image is selected as a calibration region. An input image spectral profile is generated based on comparing voxels in the first image and voxels in the calibration region, and a calibration spectral profile is generated based on comparing voxels in the calibration region with other voxels in the calibration region. Spectrally resolved images are generated by binning the first image based on histogram values computed based on the input image spectral profile. Cumulative maps are generated by extracting image intensity values from the spectrally resolved images corresponding to different spectral ranges determined from the calibration spectral profile. A second image is then generated by selectively combining the cumulative maps, wherein the second image has a second contrast weighting that is different than the first contrast weighting.

### BRIEF DESCRIPTION OF THE DRAWINGS

FIG. 1A is an example of a magnetic resonance image that can be input to a multiplexed contrast weighting technique to generate an output image with a different contrast weighting.

FIG. 1B illustrates a calibration region selected on the input image of FIG. 1A.

FIG. 2A illustrates a process of computing a statistical measure by comparing voxels in the full input image with voxels in a calibration region.

FIG. 2B illustrates a process of computing a statistical measure by comparing voxels in a calibration region with other voxels in the calibration region.

FIG. 3A illustrates an example input image spectral profile.

FIG. 3B illustrates an example calibration spectral profile.

FIG. 4A illustrates a process of determining two calibration points from a calibration profile and using those to define spectral bins or ranges for generating cumulative maps.

FIG. 4B illustrates cumulative distribution functions of the input image spectral profile and calibration spectral profile, and using these to determine a second calibration point in the example where two calibration points are determined.

FIG. 4C illustrates a process of determining three calibration points from a calibration profile and using those to define spectral bins or ranges for generating cumulative maps.

FIG. 4D illustrates cumulative distribution functions of the input image spectral profile and calibration spectral profile, and using these to determine a third calibration point in the example where three calibration points are determined.

FIG. 5 is a flowchart setting forth the steps of an example method for generating an output image with a different contrast weighting than an input image using the multiplexed contrast MRI techniques described in the present disclosure.

FIGS. 6A-6C illustrate (FIG. 6A) example spectrally resolved reconstruction of a bright-blood image, illustrating how image details are separated across spectral bins: early bins capture background (noise and lung), bins from β₀ emphasize blood pools (LA and LV), and bins beyond β₁ highlight scar structures. FIGS. 6B and 6C illustrate how SNR (FIG. 6B) and CNR (FIG. 6C) can be significantly improved compared to original bright-blood images, demonstrating self-calibrated effectiveness of the disclosed techniques.

FIG. 7 is a representative example cases of input bright-blood images and corresponding dark-blood images generated using the multiplexed contrast MRI techniques described in the present disclosure. Red arrows indicate scar, orange arrows the left atrium, and green arrows the left ventricle, positions are similar between images. SNR and CNR values are shown for each input and output image, calculated using identical ROIs. Note the significant increase in SNR and CNR across examples, including cases with compromised image quality (middle example).

FIG. 8 shows more representative example cases of input bright-blood images and corresponding dark-blood images generated using the multiplexed contrast MRI techniques described in the present disclosure. SNR and CNR values are shown for each input and output image, calculated using identical ROIs. Note the significant increase in SNR and CNR across examples, including cases with compromised image quality (e.g. first row example).

FIG. 9 is a block diagram of an example system for implementing a multiplexed contrast MRI technique to generate output images with different contrast weightings than the input images.

FIG. 10 is a block diagram of example components that can implement the system of FIG. 9.

FIG. 11 is a block diagram of an example MRI system that can implement methods described in the present disclosure.

### DETAILED DESCRIPTION

Described here are systems and methods for multiplexed contrast magnetic resonance imaging (MRI), in which a first image with a first contrast weighting is used to generate a second image with a second contrast weighting that is different from the first contrast weighting. Alternatively, multiple images each with a different contrast weighting may be generated from the first image. The second image not only has the different contrast weighting, but can advantageously have improved signal-to-noise ratio (SNR) and/or contrast-to-noise ratio (CNR) characteristics by way of the spectral encoding and reconstruction used in the disclosed methods. The second contrast weighting can differ from the first contrast weighting by suppressing image intensity values associated with a tissue, amplifying image intensity values associated with a tissue, or otherwise selectively modifying image intensity values from the first image.

In general, the multiplexed contrast method is implemented in two stages. The first stage represents a forward problem in which images are encoded into a spectral space based on a calibration region selected from an input image (e.g., the first image). The second stage represents a backward problem that decodes an inverse problem to generate one or more images with different contrast weightings than the input image (e.g., the first image). For instance, the input image is taken into an N+1 dimensional space, where the added dimension corresponds to a spectral dimension. By way of example, a two-dimensional (2D) image is taken into a three-dimensional (3D) space, where two dimensions correspond to the two spatial dimensions of the image and the third dimension corresponds to the added spectral dimension. Likewise, a 3D image can be taken into a four-dimensional (4D) space corresponding to three spatial dimensions and the added spectral dimension. Additionally or alternatively, a series of images (e.g., a time series of images, etc.) can be taken from an N+t dimensional space corresponding to N spatial dimensions and one or more series dimensions, t, (e.g., a single temporal dimension for a time series of images, etc.) to an N+t+1 dimensional space where the added dimension corresponds to the added spectral dimension.

Advantageously, the methods described in the present disclosure are capable of generating images with different contrast weightings from an input image in a self-calibrated manner, such that no training is needed. Noise and artifacts are also taken into account, and in some instances can be suppressed by moving the noise and/or artifacts into different spectral bins. Advantageously, the disclosed methods do not assume a distribution of errors, but instead can determine this information from the spectral data and the data from the calibration region.

The multiplexed contrast MRI techniques described in the present disclosure can be implemented in a number of different clinical applications. As one non-limiting example, dark-blood imaging can be provided by inputting bright-blood images to generate images in which blood signals are suppressed (i.e., thereby generating dark-blood images). This dark blood imaging can be used for cardiac applications, brain angiography, or other general angiography techniques. Additionally or alternatively, the multiplexed MRI methods can be used to generate other contrast weightings, including those based on T1-rho, cerebral spinal fluid (CSF) suppression, or the like.

Advantageously, the methods described in the present disclosure can be used for treatment guidance, such as surgical guidance, ablation guidance, or the like. Additionally or alternatively, the methods can be used for post-treatment evaluations, such as evaluation recurrence, success, etc., after an ablation procedure. The methods can also be used to determine the amount of fibrosis, scar, or other tissue pathologies or conditions by creating unique contras weightings that emphasize these tissues.

In still other applications, the images generated using the disclosed methods can be used to train machine learning models for generating spectrally reconstructed images with different contrast weightings. In these instances, the first and second images (i.e., the inputs and outputs of the multiplexed contrast MRI techniques) can be used as training pairs for training a machine learning model to generate images with different contrast weightings. As an example, a generative adversarial network (GAN) or other suitable machine learning model could be trained in this manner.

The multiplexed contrast MRI techniques described in the present disclosure can also be applied across different magnetic field strengths to address field-specific imaging challenges.

In low-field MRI applications (e.g., field strengths below approximately 1.5 Tesla, such as 0.5 Tesla or lower), where SNR limitations may constrain diagnostic utility, the retrospective self-calibrated reconstructions can increase CNR and SNR to improve detectability from existing acquisitions without requiring additional scan time. By extracting latent contrasts from acquired image data, the methods can support tumor detection and characterization in the abdomen and pelvis, enhance visualization of lung parenchyma and pulmonary nodules, improve brain lesion conspicuity, facilitate musculoskeletal soft-tissue assessment, enable vessel wall and plaque imaging, and enhance myocardial scar and fibrosis detection. In some cases, these capabilities may extend the clinical utility of low-field MRI systems by providing image quality improvements that approach those achievable at higher field strengths.

In high-field MRI applications (e.g., field strengths of approximately 3.0 Tesla or greater, such as 7.0 Tesla), where increased signal availability may be accompanied by field-dependent contrast variability, the multiplexed contrast MRI techniques can increase CNR and SNR while stabilizing contrast behavior. The self-calibrated nature of the spectral encoding may adapt to field-specific signal characteristics, improving delineation of fine structures and subtle pathology. Applications at high field strength may include intracranial vessel wall and plaque imaging, cortical and subcortical lesion characterization in epilepsy and multiple sclerosis, tumor microstructure and margin assessment in neurological and abdominal imaging, peripheral vessel wall evaluation, and visualization of therapy effects such as post-ablation or post-treatment tissue changes. In some aspects, the spectral separation provided by these methods may help distinguish subtle signal differences that become more apparent at higher field strengths.

As noted above, the multiplexed contrast MRI techniques described in the present disclosure generally include two stages. In the first stage, spectral probabilistic profile encodings are generated. In the second stage, the spectral profiles are used for self-calibration of a spectral-resolved reconstruction and/or mapping to generate images with a different contrast weighting. A non-limiting example of each of these stages is described below in more detail.

In the first stage of the multiplexed contrast MRI techniques described in the present disclosure, an input image is processed to determine spectral profiles that can be used to generate images with different contrast weightings than the input image in the second stage of the multiplexed contract MRI technique.

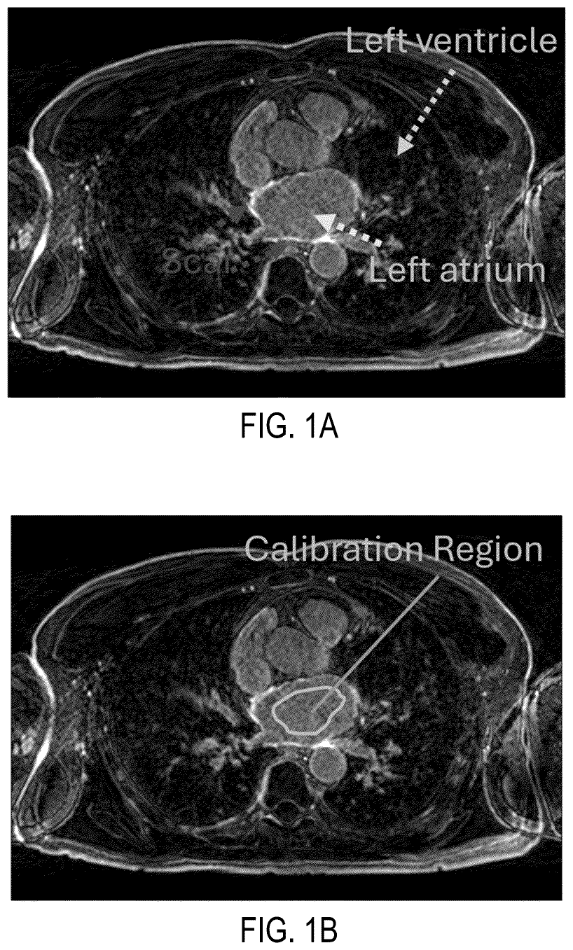

The method includes selecting an input image for processing and determining one or more calibration regions in the input image. For example, a region-of-interest (ROI) can be selected in the input image can be selected as the calibration region. An example input image is illustrated in FIG. 1A and an example calibration region selected in this input image is illustrated in FIG. 1B. In general, the calibration region is selected as a region of the input image that contains tissues or other signals that should be suppressed in the second stage of the multiplexed contrast MRI technique. As one non-limiting example, the calibration region can be selected as an ROI containing blood. The blood may be, for example, bright blood (i.e., blood with high image intensity values in the input image). For cardiac MRI applications, the blood-containing ROI may, for example, be selected as a left atrium (LA) blood pool. In other examples, the calibration region can be selected to contain tissues or other signal sources other than blood, such as cerebral spinal fluid (CSF), fat, muscle, or the like.

The input image and calibration region can be defined as follows. Define I=[gᵢ] as a linear vector of gray value intensities of the input image, where i=1, . . . , N and N is the total image linear voxel count (width×height). Define C=[gⱼ] as the linear intensity vector for the ROI defining the image intensity distribution to be suppressed, with j=1, . . . , M and M as the voxel count in the ROI. An example input image and image with a calibration region selected and identified is illustrated in FIG. 1. In the illustrated example, a single calibration region is selected. In other instances, more than one calibration region may be selected. Preferably, the multiple calibration regions will each contain the same or similar tissue types. For instance, multiple calibration regions can be selected as each containing blood pool signal. Alternatively, the multiple calibration regions may be selected as containing different tissue types, such that multiple output images can be generated with different contrast weightings based on using each different calibration region as the basis for generating images with different contrast weightings.

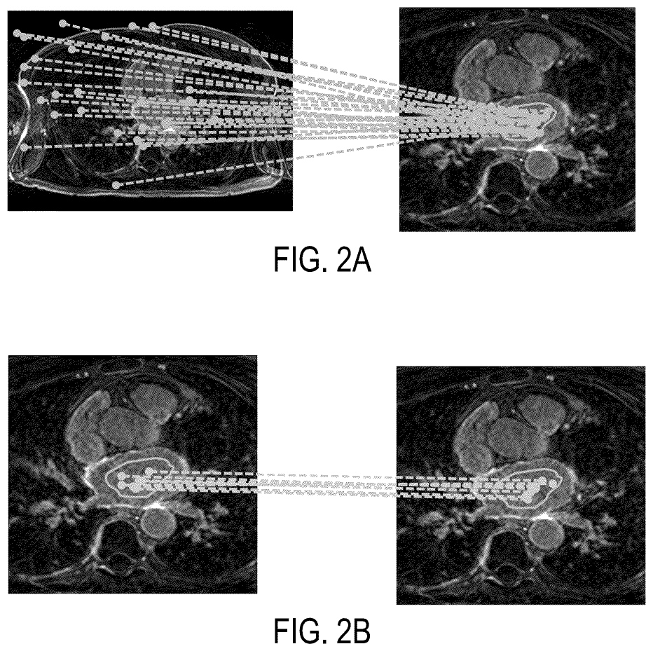

Once the calibration region is selected, spectral profiles are constructed based on statistical measures between the input image and the calibration region. As a first step, one or more statistical measurements are calculated, which may be statistical measures between voxels in the input image and voxels in the calibration region, statistical measures between voxels within the calibration region, and so on. The statistical measures may measure similarity between voxels, dissimilarity between voxels, disparity between voxels, and so on. FIG. 2A illustrates an example in which a statistical measure is determined by comparing voxels in the input image with voxels in the calibration region, and FIG. 2B illustrates an example in which a statistical measure is determined by comparing voxels in the calibration region with other voxels in the calibration regions. As a non-limiting example, a cross-disparity measure and a auto-self-disparity measure can be calculated.

Cross-disparities can be calculated between each voxel in the input image and the calibration region. For instance, a cross-disparity vector Φ_{cross} between the in put image, I, and the calibration region, C, can be calculated as:

$${Φ}_{c r o s s} ( I , C ) = {[ {g}_{i} \cdot {g}_{j} ]}_{1 \leq i \leq N , 1 \leq j \leq M} \qquad ( 1 )$$

where gᵢ∈I and gⱼ∈C. This creates a vector of cross-disparity values, where the vector has length N×M containing all pairwise products between elements in I and C.

Calibrating auto-self-disparity Φ_{auto_calib} can be calculated between the calibration region C and itself as:

$${Φ}_{auto \_ calib} ( C , C ) = {[ {g}_{j} \cdot {g}_{l} ]}_{1 \leq l \leq M , j \leq l \leq M} \qquad ( 2 )$$

where gⱼ∈C and gₗ∈C. This creates a vector Φ_{auto_calib} of length M×(M−1)/2.

Using the statistical measures, spectral profiles are then constructed. For example, the probability density functions (PDFs) of Φ_{cross} and Φ_{auto_calib} can be used to create spectral intensity profiles of the image (S_{I}) and the calibration region (S_{C}). The PDFs can be segmented into a number of bins, such as B=100 probabilistic bins.

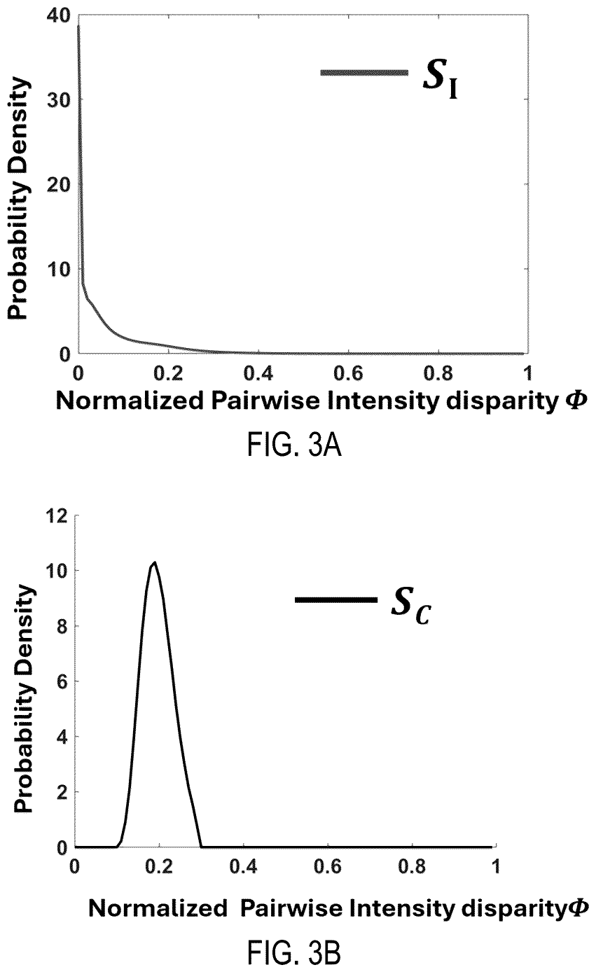

The spectral profile of the input image can be computed as:

$${S}_{I} = p d f ( {Φ}_{c r oss} , B ) \qquad ( 3 )$$

where pdf is the probability density function estimated as a normalized histogram with B bins. FIG. 3A illustrates an example of an input image spectral profile. Additionally or alternatively, the input image spectral profile can be generated as a histogram of the cross-disparity values. The spectral profile of the calibration region can be computed as:

$${S}_{C} = p d f ( {Φ}_{a uto - caiib} , B ) \qquad ( 4 )$$

where pdf is the probability density function estimated as a normalized histogram with B bins. FIG. 3B illustrates an example of a calibration spectral profile. Additionally or alternatively, the calibration spectral profile can be generated as a histogram of the auto-self-disparity values.

Calibration points are determined from the calibration spectral profile, S_{C}, which will be used in the second stage of the multiplexed contrast MRI process. As an example, calibration points βₖ (with i=0, . . . , K−1 for K≥2 calibration points) can be determined from the calibration spectral profile, S_{C}, and a cumulative density function (CDF) of the calibration spectral profile. A first calibration point, β₀, can be defined as the first bin index for which the calibration spectral profile is greater than zero. In this way, bins β<β₀ correspond to background or sub-calibrator noise. In examples where K=2, the second calibration point, β₁, can be defined as the bin index where the CDF of the calibration region is first equal to a threshold value, which may be equal to one as an example. In examples where K=3, a second calibration point, β₁, can be defined as the mode of the calibration spectral profile, representing the most probable pure calibrator response (i.e., the core of the calibrator spectrum), and a third calibration point, β₂, marks the practical end of the calibrator distribution and can be defined as the bin index where the CDF of the calibration region is first equal to a threshold value, which may be equal to one as an example. In practice, the third calibration point β₂ can be set as the smallest bin index with CDF (β₂)≥1−ε, so at most an ε-fraction of calibrator mass lies beyond β₂, avoiding overfitting the uncertainty-dominated tail. Bins β>β₂ are supra-calibrator enhancements corresponding to scar and other highly enhanced structures. Together, the calibration points (β₀, β₁, β₂) delineate sub-calibrator, core-calibrator, and supra-calibrator regimes used as scan-specific integration bounds in Stage 2. Additionally or alternatively, the one or more bins can be defined from the calibrating profile to serve as calibrating bins. In those instances, a resulting image can be formed as a combination and/or function of the spectrally resolved images bounded by the bins according to a function.

The calibration points can be used to derive bin ranges for cumulative bins φ₁, φ₂, and φ₃ for reconstructing images with different contrast weightings in the second stage of the multiplexed contrast MRI process. In general, when three calibration points are defined, bins below β₀ lie below the calibration distribution and predominantly accumulate background and very low-signal voxels, bins between β₀ and β₁ aggregate voxels whose spectral contributions follow the lower portion of the calibrator (calibrator-like) distribution, bins between β₁ and β₂ capture the core and upper part of the calibrator distribution corresponding to the main bright-calibrator (e.g., bright blood) component, and bins above β₂ accumulate supra-calibrator high-signal voxels, including scar and other structures whose disparity products extend beyond the main calibrator distribution.

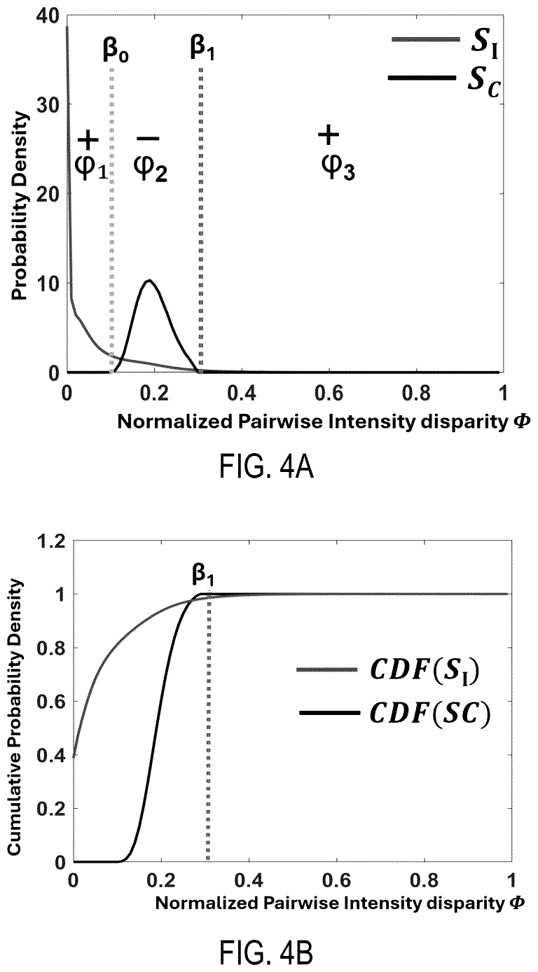

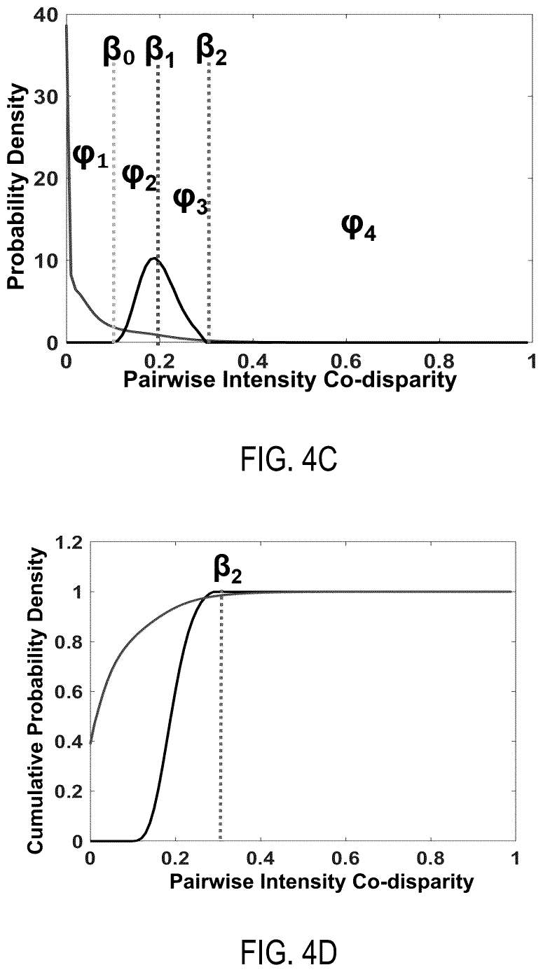

FIG. 4A illustrates an example of how the first and second calibration points in the K=2 example discussed above can be used to define different spectral bins or ranges for constructing different cumulative maps. FIG. 4B illustrates CDFs for the input image and calibration spectral profiles and how a second calibration point can be determined based on the CDF of the calibration spectral profile. FIG. 4C illustrates an example of how the first, second, and third calibration points in the K=3 example discussed above can be used to define different spectral bins or ranges for constructing different cumulative maps. FIG. 4D illustrates CDFs for the input image and calibration spectral profiles and how a third calibration point can be determined based on the CDF of the calibration spectral profile.

In general, in the second stage of the multiplexed contrast MRI techniques described in the present disclosure, spectral profiles and calibrating bins determined in the first stage of the multiplexed contrast MRI technique are used to reconstruct or otherwise generate images with a different contrast weighting than the input image. For example, the different contrast weightings can include contrast weightings where image intensities associated with the calibration region are nulled or otherwise suppressed.

The method includes defining spectral bin ranges for the reconstruction based on the input image spectral profile. For each bin in the input image spectral profile, S_{I}, calibrating bins β_{low} and β_{high} can be set as the lowest and highest Φ_{cross} values in that bin, defining the target range (bin edges) for Φ_{cross} for that bin.

The set of i indices in input image I are then retraced from the computed disparities Φ_{cross} (I,C) that produce values within the defined bin range. Indices can be identified as follows:

$$\{ i \vert {δ}_{[ {β}_{l o w} , {β}_{h i g h} ]} ( {Φ}_{c r o s s} ( {g}_{i} \cdot {g}_{j} ) ) = 1 \} \qquad ( 5 )$$

$$where {δ}_{[ {β}_{low} , {β}_{high} ]} = \{ \begin{matrix}1 , & if ( {Φ}_{cross} ( {g}_{i} \cdot {g}_{j} ) ∈ [ {β}_{low} , {β}_{high} ] \\ 0 , & otherwise\end{matrix}$$

This step may result in repeated indices if a voxel is paired with multiple voxels that satisfy the bin range. From the selected indices, then, a unique set of indices, U, can be extracted by selecting indices without duplicates:

U={i:i appears in the bin range without duplicates} (6)

The relative contribution of each unique index to the bin is then calculated. As a non-limiting example, a normalized frequency calculation can be implemented. For each unique index u∈U, the histogram value h(u) can be calculated as the count of times u appears in pairwise products within the bin range:

$$h ( u ) = \frac{{\sum }_{j = 1}^{M} {δ}_{[ {β}_{low} , {β}_{high} ]} ( {Φ}_{c r o s s} ( {g}_{u} \cdot {g}_{j} ) )}{{\sum }_{i = 1}^{N} {\sum }_{j = 1}^{M} {δ}_{[ {β}_{low} , {β}_{high} ]} ( {Φ}_{c r o s s} ( {g}_{i} \cdot {g}_{j} ) )} \qquad ( 7 )$$

Spectrally resolved images are then reconstructed for each bin. Per each bin index βᵣ, for each linear index u, its corresponding image coordinates (x, y) in the input image, I, are found. Then, the intensity value in the reconstructed image \hat{φ}(x, y, βr) is set as:

$$\hat{ϕ} ( x , y , β r ) = h ( u ) \qquad ( 8 )$$

where r=1 . . . . B, B is the number of bins in the input image spectral profile, S_{I}. This process is repeated for each bin in the input image spectral profile, thereby resulting in bin image data in one higher dimension (i.e., the added spectral dimension) than the original data: the spectral dimension. In this way, the bin images include a spectrally resolved dimension that can be used to create an image with the different contrast weighting than the input image. For a 3D input volume I(x,y,z), stacking the B bin-specific maps along the spectral axis forms the full 4D spectral-resolved volume φ(x,y,z,βᵣ), i.e., the (N+1)-dimensional representation of the image in the spectral calibrator-conditioned domain.

Using the calibration points β₀, β₁ determined in the first stage, spectral cumulative maps φ₁, φ2, φ3 are computed as:

$${φ}_{1} ( x , y ) = {\sum }_{q = 1}^{{β}_{0}} \hat{ϕ} ( x , y , β q ) ; \qquad ( 9 )$$

$$φ2 ( x , y ) = {\sum }_{v = β 0 + 1}^{β 1} \hat{ϕ} ( x , y , β v ) ; \qquad ( 10 )$$

$$φ3 ( x , y ) = {\sum }_{z = β 1 + 1}^{B} \hat{ϕ} ( x , y , β z ) ; \qquad ( 11 )$$

where x=1 . . . . W, the width of the input image and y=1 . . . . H, the height of the input image; and where B is the total number of bins in the input image spectral profile. For the case when K=3 spectral points are instead determined, the spectral cumulative maps are computed as:

$${φ}_{1} ( x , y ) = {\sum }_{q = 1}^{{β}_{0}} \hat{ϕ} ( x , y , z , β q ) ; \qquad ( 12 )$$

$$φ2 ( x , y ) = {\sum }_{v = β 0 + 1}^{β 1} \hat{ϕ} ( x , y , z , β v ) ; \qquad ( 13 )$$

$$φ3 ( x , y ) = {\sum }_{r = β 1 + 1}^{β 2} \hat{ϕ} ( x , y , z , β r ) ; \qquad ( 14 )$$

$$φ4 ( x , y ) = {\sum }_{k = β 2 + 1}^{B} \hat{ϕ} ( x , y , z , β k ) . \qquad ( 15 )$$

These cumulative maps capture different image details of the input image, including background tissue signals and signals associated with tissue having different contrast properties. In the K=3 construction, φ1 predominantly accumulates background and very low-signal voxels below the onset of the calibrator distribution; φ2 aggregates voxels whose spectral contributions follow the lower portion of the calibrator (calibrator-like) distribution; φ3 captures the core and upper part of the calibrator distribution corresponding to the main bright-calibrator (e.g., bright blood) component; and φ4 accumulates supra-calibrator high-signal voxels, including scar and other structures whose disparity products extend beyond the main calibrator distribution. In the non-limiting example of angiography applications, the cumulative maps can capture image details such as blood regions and scar regions.

The cumulative maps are then combined to generate an image with a different contrast weighting than the input image. As an example, the cumulative maps can be combined into an image, Ψ, as follows:

$$Ψ ( x , y ) = φ1 ( x , y ) - φ2 ( x , y ) + φ3 ( x , y ) ; \qquad ( 16 )$$

for K=2 calibration points or as follows

$$Ψ ( x , y ) = [ φ2 ( x , y , z ) - φ1 ( x , y , z ) ] + [ φ4 ( x , y , z ) - φ3 ( x , y , z ) ] ; \qquad ( 17 )$$

for K=3 calibration points. In Eqn. (17), the two difference terms provide complementary contrasts. The first, φ2−φ1, suppresses background and low-signal fluctuations encoded in φ1 while preserving structural detail in the lower calibrator-related band, φ2. The second difference term, φ4−φ3, yields dark-blood contrast by suppressing the main bright-calibrator component in φ3 and retaining supra-calibrator signal in φ4, including scar and other high-intensity enhancements. Their sum produces an N-dimensional image with reduced background noise, nulled calibrator compartment (e.g., blood pool in some examples), and accentuated supra-calibrator enhancement. After computing the image, Ψ(x,y), in some implementations its values can be shifted to start from zero and scale the result to a range of 0 to 4095 (i.e., a 12-bit range) for display and quantitative analysis.

Additionally or alternatively, the final output image with the different contrast weighting can also be generated based on combinations of the spectral bins (e.g., combinations of the spectrally resolved images). In still other examples, the spectral bins (i.e., spectrally resolved images) can be output themselves as the output image with the different contrast weighting.

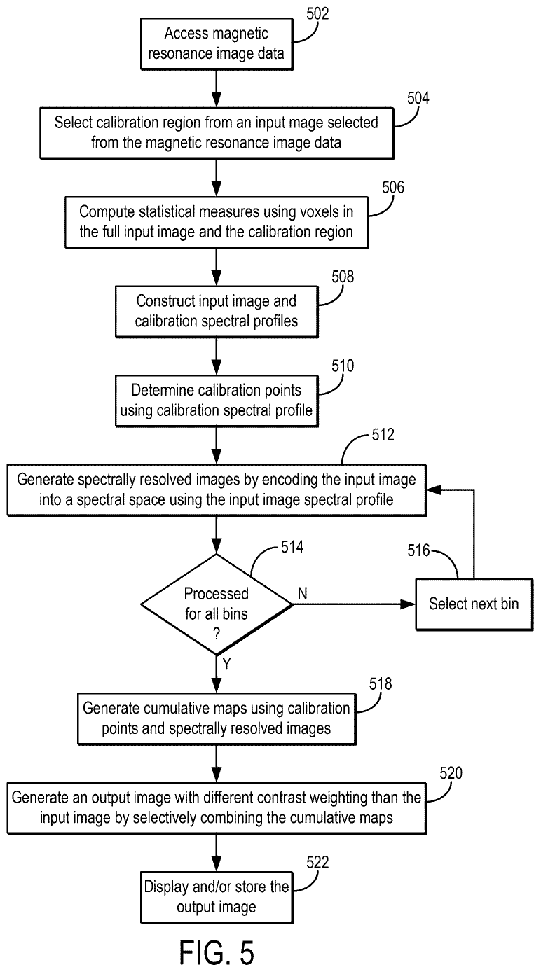

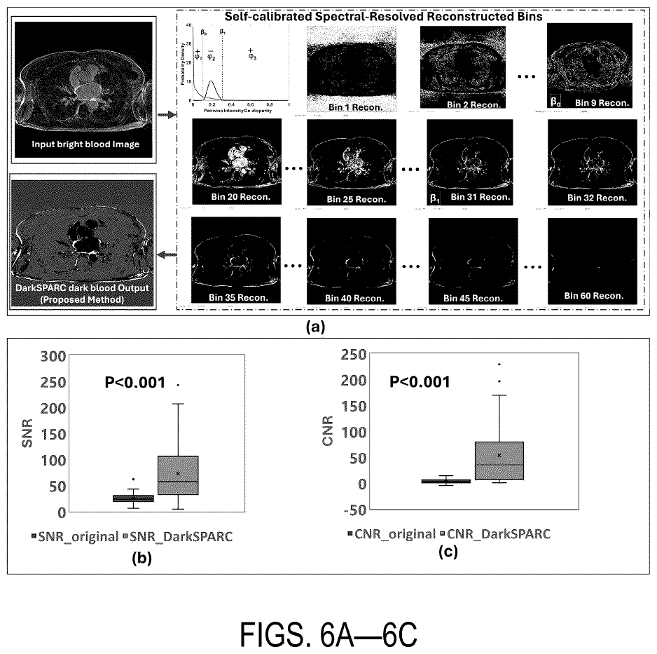

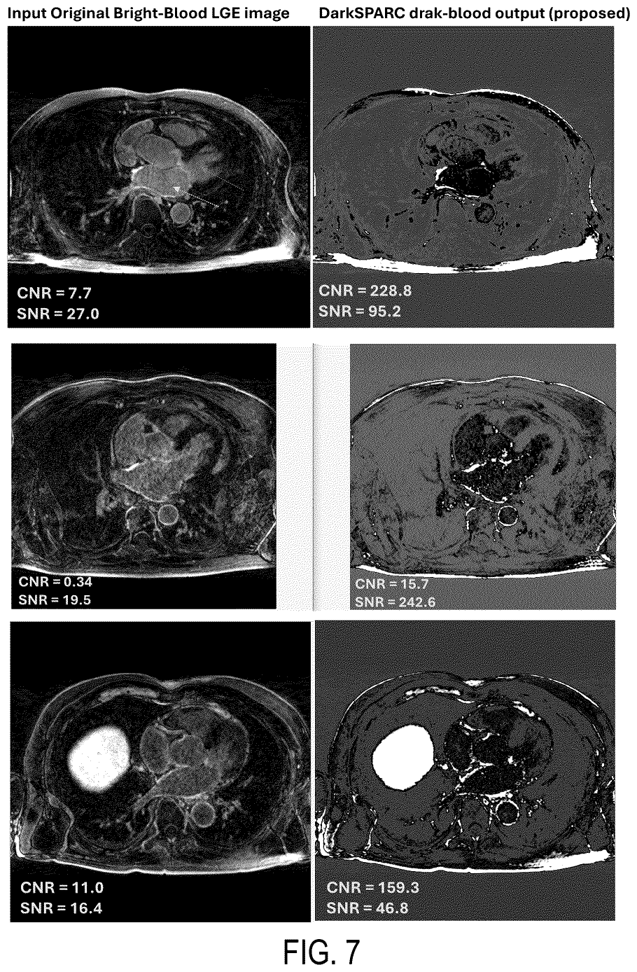

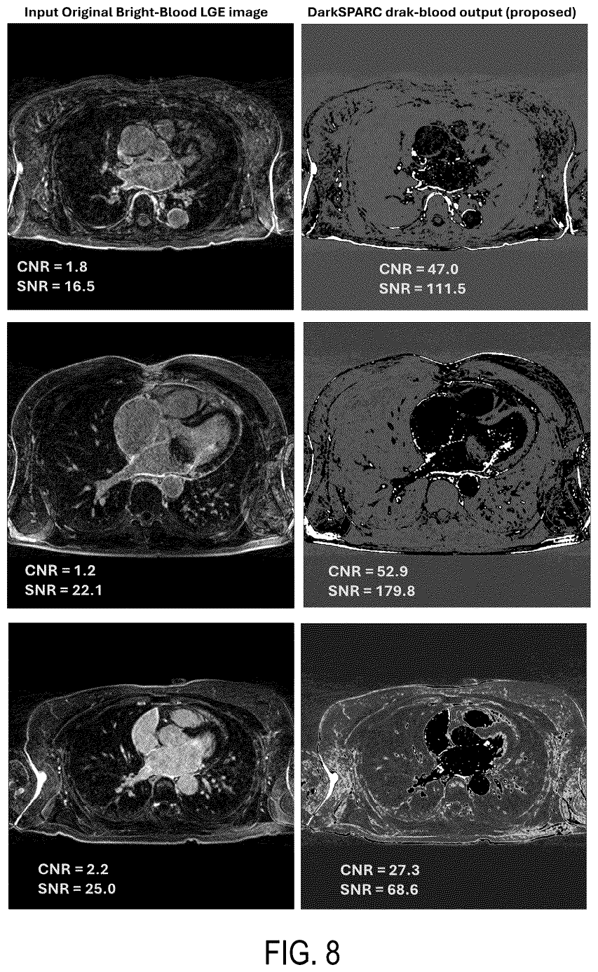

Referring now to FIG. 5, a flowchart is illustrated as setting forth the steps of an example method for multiplexed contrast MRI.

The method includes accessing magnetic resonance image data with a computer system, as indicated at step 502. Accessing the magnetic resonance image data may include retrieving such data from a memory or other suitable data storage device or medium. Additionally or alternatively, accessing the magnetic resonance image data may include acquiring such data with an MRI system and transferring or otherwise communicating the data to the computer system, which may be a part of the MRI system.

The magnetic resonance image data include one or more images acquired with a first contrast weighting. As one non-limiting example, the images may be bright-blood images, such as those acquired using an LGE scan, or the like.

An input image is selected for processing from the magnetic resonance image data and a calibration region is then selected from the input image, as indicated at step 504. The calibration region is selected as containing a tissue or other image feature that will be suppressed, amplified, or otherwise modified to provide the different contrast weighting in the output images. As one non-limiting example, the calibration region may be selected as a region containing a blood pool signal. Additionally or alternatively, the calibration region may be selected as containing other tissue types, such as muscle, fat, cerebrospinal fluid (CSF), white matter, gray matter, bone, ligaments, tendons, and so on. As described above, in some embodiments more than one calibration region may also be selected.

Two or more statistical measures are then computed based on the input image and the calibration region, as indicated at step 506. The statistical measures may indicate a similarity between voxels, a dissimilarity between voxels, a disparity between voxels, and so on. As an example, a cross-disparity can be calculated between voxels in the input image and voxels in the calibration region. Additionally, an auto-disparity can be calculated between voxels in the calibration region.

A spectral profile for the input image and a spectral profile for the calibration region are then constructed, as indicated at step 508. As described above, the spectral profiles can be constructed based on probability density functions (PDFs) of the statistical measures computed in step 506. Thus, as one non-limiting example, an input image spectral profile can be constructed as the PDF of the cross-disparity measure and a calibration spectral profile can be constructed as the PDF of the auto-disparity measure.

Calibration points are then identified or otherwise determined based on the spectral profiles, as indicated at step 510. In general, the calibration points help define the spectral ranges that will be used when generating images with different contrast weightings from the input image. As a non-limiting example, a first calibration point, β₀, can be based on a bin index determined as the first bin index for which the calibration spectral profile is greater than zero. Likewise, an second calibration point, β₁, can be based on a bin index determined as the bin index where the cumulative density function of the calibration spectral profile first equals one. Alternatively, the second calibration point can be based on the mode of the calibration spectral profile, representing the most probable pure calibrator response. In these instances, a third calibration point, β₂, can be based on a bin index determined as the bin index where the cumulative density function of the calibration spectral profile first equals one (or first equals 1−ε, where ε is a small value to avoid overfitting the uncertainty-dominated tail).

More generally, the calibration points are determined to define spectral bins or ranges into which image intensities or other image data can be encoded. In this way, different characteristics of the input image can be suppressed, amplified, or otherwise modified to achieve different contrast weightings or other image enhancements. As one example, different contrast weightings can be achieved by suppressing image intensity values associated with tissues in the calibration region. As another example, different contrast weightings can be achieved by amplifying image intensity values relative to tissues in the calibration region. In still another example, the calibration points can define spectral bins or regions into which noise and/or artifacts can be encoded. In these instances, the different contrast weighting can be achieved by suppressing the noise and/or artifacts that have been encoded into unique spectral bins or ranges.

Spectrally resolved images are then generated for each spectral bin, as indicated at step 512. First, lower and upper bin edges are defined for each bin in the input image spectral profile. As an example, the lower bin edge can be determined as the lowest values in that bin and the upper bin edge can be determined as the highest values in that bin. As described above, the set of indices in the input image can then be retraced from the computed cross-disparities, or other statistical measures computed between the input image and calibration region, that produce values within the bin range defined by the lower and upper bin edges. From these selected indices, a unique set of indices is extracted; that is, indices that appear in the bin range without any duplicates. The relative contribution of each unique index to the bin is then calculated using, for example, a normalized frequency calculation. This results in a histogram value, h(u), that can be used for generating the spectrally resolved images.

For each bin index, βᵣ, for each linear index, u, the image coordinates (x, y) in the input image are determined. The image intensity values in the spectrally resolved images are then set as the histogram value, \hat{φ}(x,y,βᵣ)=h(u), as described above. The index, r, spans the range of bins in the input image spectral profile. The resulting spectrally resolved images, therefore, have an added spectral dimension defined based on the histogram values determined in step 512. As indicated at decision block 514, step 512 is repeated for each bin in the input image spectral profile by selecting the next bin at step 516 and repeating step 512.

Using the spectrally resolved images and the calibration points, cumulative maps are generated, as indicated at step 518. As a non-limiting example, three cumulative maps (for K=2 calibration points) can be generated: a first cumulative map φ₁ corresponding to spectrally resolved map data below the first calibration point, β₀; a second cumulative map φ₂ corresponding to spectrally resolved map data between the first calibration point β₀ and the second calibration point, β₁; and a third cumulative map φ₃ corresponding to spectrally resolved map data above the second calibration point, β₁. In examples where more than two calibration points are determined, more than three cumulative maps may be generated. For example, when K=3 calibration points are determined, four cumulative maps can be generated: a first cumulative map φ₁ corresponding to spectrally resolved map data below the first calibration point, β₀; a second cumulative map φ₂ corresponding to spectrally resolved map data between the first calibration point β₀ and the second calibration point, β₁; a third cumulative map φ₃ corresponding to spectrally resolved map data between the second calibration point, β₁, and the third calibration point, β₂; and a fourth cumulative map φ₄ corresponding to spectrally resolved map data above the third calibration point, β2. As described above, in some examples the cumulative maps may be generated using equations (9)-(11) or (12)-(15).

The cumulative maps can then be selectively combined to generate an image of the subject with a second contrast weighting that is different from the first contrast weighting, as indicated at step 520. For example, the second image can be generated by combining the cumulative maps based on equation (12). In this example, the second cumulative map (corresponding to the spectrally resolved map data between the first and second calibration points) is subtracted from the sum of the first and third cumulative maps. As a result, the image intensity values associated with tissues in the calibration region are suppressed in the second image. In this way, the second contrast weighting can differ from the first contrast weighting by way of image intensity values corresponding to tissues in the calibration region being nulled or otherwise suppressed. As a non-limiting example, the first contrast weighting may include bright image intensity values for blood, whereas the second contrast weighting may include nulling or otherwise suppressing the image intensity values for blood. In this way, the methods described in the present disclosure can be used to generate so-called black-blood images from bright-blood images, such as those acquired using LGE scanning techniques.

As described above, in other examples the second contrast weighting may include selectively amplifying image intensity values relative to tissues in the calibration region (e.g., by weighting values in the cumulative maps associated spectral bins or ranges). In still other examples, the second contrast weighting may include selectively suppressing noise and/or artifacts by selectively weighting or removing cumulative maps associated with spectral bins or ranges into which the noise and/or artifacts have been encoded.

More generally, selectively combining the cumulative maps may include computing a difference between two or more cumulative maps, computing a sum of two or more cumulative maps, and/or combining two or more cumulative maps according to a function. Additionally or alternatively, one or more of the cumulative maps may be weighted or otherwise modulated while combining the cumulative maps.

As also described above, in some additional embodiments the output image can be generated by combining spectrally resolved images rather than the cumulative maps. In these instances, the spectrally resolved images may also be combined by computing a difference between two or more spectrally resolved images, computing a sum of two or more spectrally resolved images, and/or combining two or more spectrally resolved images according to a function. The spectrally resolved images may be weighted or otherwise modulated while combining the spectrally resolved images.

In still other examples, a spectrally resolved image and/or cumulative map may be stored as the output image with the different contrast weighting.

The second images generated by selectively combining the cumulative maps can then be displayed to a user, stored for later use or further processing, or both, as indicated at step 522. In some implementations, particularly for cardiac applications involving scar quantification, a scar-floor threshold can be defined to ensure quantitative traceability of ground-truth scar. The scar-floor threshold, T, can be defined as:

$$T = {μ}_{pool} + 3.3 {σ}_{pool} ; \qquad ( 18 )$$

where μₚₒₒₗ and σₚₒₒₗ are the mean and standard deviation of the blood-pool intensities, respectively. This threshold has been histologically validated and can be used to define scar regions in both the input bright-blood images and the output dark-blood images generated using the multiplexed contrast MRI techniques described herein. The scar-floor threshold enables consistent scar quantification across different imaging conditions and can be applied to determine the percentage of tissue (e.g., left atrial wall) that exhibits scar characteristics. Voxels with intensity values greater than or equal to the threshold T can be classified as scar tissue, enabling accurate scar burden assessment in post-ablation patients and other clinical applications.

### EXAMPLES

As a non-limiting example, the systems and methods described in the present disclosure can be advantageously used to generate dark-blood images for magnetic resonance angiography applications. In this example, the multiplexed contrast MRI techniques may be referred to as a Dark SPectral self-calibrAted ReconstruCtion (DarkSPARC). As described above, DarkSPARC reprocesses image data into a “spectral” space, where intensities are calibrated to selectively suppress blood signal while enhancing tissue and scar visibility, effectively boosting contrast-to-noise (CNR) by up to 14-fold and signal-to-noise (SNR) by 2-fold in post-ablation atrial fibrillation patients. This self-calibrating technology streamlines workflow, reduces patient burden, and enhances clinical usability.

Beyond LGE for atrial fibrillation, the versatile spectral encoding of the multiplexed contrast MRI techniques described in the present disclosure can benefit MRI angiography for vessel wall and vascular imaging, including intracranial imaging for brain vessels, plaque visualization in carotid arteries, aortic and pulmonary artery assessment, and peripheral artery evaluation for diagnosis and intervention planning.

In an example study, the multiplexed contrast MRI techniques described in the present disclosure were evaluated on 48 atrial fibrillation (AF) patients, 3-4 months post-ablation, where each patient had bright-blood 3D LGE MRI data (reconstructed voxel size=0.625×0.625×1.25 mm). A single slice containing the pulmonary vein (PV) and left LA was selected for each patient to validate the performance of the multiplexed contrast MRI techniques described in the present disclosure in detecting post-ablation scar. The dataset also provided LA myocardium segmentation.

SNR was computed for the left atrial (LA) myocardial wall (including all wall, not just scar regions), using a region of interest in the lung to determine tissue standard deviation. CNR was calculated between the LA myocardial wall and an ROI in the blood pool. Differences in SNR and CNR between bright-blood and DarkSPARC dark-blood images were tested using Wilcoxon's paired sign-rank test, presented as median [25% tile, 75% tile].

The DarkSPARC method achieved ~14-fold increase in CNR, reaching in 35.2 [6.2, 78.5] compared to 2.6 [0.26, 6.3] in the original images (p<0.001), as shown in FIG. 3C. SNR also significantly improved, with a two-fold increase to 57.5 [32.2, 105.6] from 23.5 [19.2, 30.1] (p<0.001), as shown in FIG. 3A. Processing time per patient (one slice) was 2.3 [1.8, 2.8] minutes, involving 0.85 [0.68, 1.1] billion cross-disparities. FIG. 3A shows example spectrally resolved reconstructions of bright-blood images. FIGS. 4 and 5 present example cases with DarkSPARC dark-blood images showing improved CNR and SNR.

The DarkSPARC method described in the present disclosure efficiently generates left atrial dark-blood LGE images from bright-blood acquisitions, achieving a two-fold SNR and 13-fold CNR boost. By reencoding intensities into calibration-conditioned spectral bins, DarkSPARC separates image details, suppresses noise, and maintains computational efficiency with a linear, vectorized algorithm. Eliminating separate acquisitions and complex timing, DarkSPARC streamlines workflow and enhances clinical usability with self-calibration that adapts to noise and artifacts. The flexible spectral encoding provided by these methods may extend to other MRI applications, such as brain and carotid vessel imaging.

The following example illustrates another non-limiting example of the spectral reconstruction techniques described herein, demonstrating the application of a DarkSPARC reconstruction method to convert standard bright-blood 3D left atrial LGE MRI into dark-blood images for post-ablation scar imaging.

The example utilized a public dataset including 60 post-ablation 3D LA LGE scans from three centers, acquired from patients who had undergone catheter ablation for atrial fibrillation. Scans were acquired on various 1.5T MRI systems using free-breathing, navigator-gated 3D LGE protocols. Spatial resolutions ranged from approximately 0.625×0.625×2.5 mm to 1.4×1.4×1.4 mm depending on the acquisition center and protocol. For all cases, the dataset provided 3D LA LGE images plus binary LA cavity and scar masks.

The spectral reconstruction method was implemented as described above. A calibrator region of interest (ROI) was defined within the left atrial blood pool. The calibrator vector C=[gⱼ], j=1, . . . , M was defined as the set of voxel intensities within this blood-pool ROI, where M represents the number of calibrator voxels.

In a first stage (spectral probabilistic profile encoding), the algorithm operated on the full bright-blood image intensity vector I=[gᵢ], i=1, . . . , N voxels. Two disparity vectors were computed. A cross-disparity vector mapped the entire image into calibrator space via pairwise products as described above. A calibrating auto-disparity vector characterized the intrinsic behavior of the calibrator as also described above. The statistical distributions of these disparity vectors were summarized as normalized histograms with B=100 bins, yielding an Image Spectral Profile S_{I} and a Calibrating Spectral Profile S_{C}.

Scan-specific calibration landmarks (β₀,β₁,β₂) were derived from S_{C} and its cumulative density function CDF_{S}_{_{C}}. As described above, β₀ represents the first spectral bin with nonzero calibrator density (bins below corresponding to background or sub-calibrator noise), β₁ represents the mode of S_{C} (the most probable pure calibrator response), and β₂ marks the practical end of the calibrator distribution (bins above corresponding to supra-calibrator enhancements such as scar).

In a second stage (self-calibrated spectral-resolved reconstruction), for an input 3D LGE volume I(x, y, z) of size X×Y×Z, the method generated B bin-specific spatial maps along the spectral axis, yielding a 4D spectral-resolved volume φ(x,y,z,βᵣ), βᵣ∈{1, . . . , B}. For each bin, contributing voxels from the original image were identified using an indicator function based on whether their cross-disparity products fell within the bin range.

The spectral-resolved volume was projected back into spatial representation by integrating along the spectral axis using the calibration landmarks as integration limits, yielding four cumulative spectral maps, as described above. In this construction, φ₁ predominantly accumulated background and very low-signal voxels; φ₂ aggregated voxels following the lower portion of the calibrator distribution; φ₃ captured the core and upper part of the calibrator distribution corresponding to the main bright-blood component; and φ₄ accumulated supra-calibrator high-signal voxels including scar.

The final dark-blood image Ψ was obtained by combining these four component maps via the dual-contrast formulation shown above in Eqn. (17). The first difference term (φ₂−φ₁) suppressed background and low-signal fluctuations while preserving structural detail. The second difference term (φ₄−φ₃) yielded dark-blood contrast by suppressing the main bright-blood component and retaining supra-calibrator signal including scar.

A scan-specific numerical phantom framework was developed to validate the reconstruction method with known ground-truth scar burden. Five clinical LA LGE datasets were selected corresponding to the 5th, 25th, 50th, 75th, and 95th percentiles of baseline scar-to-blood-pool contrast-to-noise ratio (CNR). For each baseline case, four ground-truth phantoms were constructed: a native phantom with original scar percentage, and phantoms with scar cloned to 10%, 20%, and 30% of LA wall volume.

Phantom construction employed two stages. In a first stage (normal tissue cloning), original intensity values within the LA wall mask were replaced with intensities cloned from the patient's own remote myocardium using inverse CDF mapping to preserve spatial texture while ensuring uncontaminated normal tissue. In a second stage (scar cloning), scar was imposed using a threshold T=μₚₒₒₗ+3.3σₚₒₒₗ, where μₚₒₒₗ and σₚₒₒₗ are the mean and standard deviation of blood-pool intensities.

Each of the 20 ground-truth phantoms was subjected to controlled CNR degradation at 9 levels (10-90% CNR reduction in 10% steps) plus the non-degraded baseline, yielding 200 phantom experiments.

Across all baseline CNR levels, scar burdens, and degradation steps, the spectral reconstruction method increased LA scar-pool CNR, SNR, and effective CNR (eCNR) relative to bright-blood in every phantom experiment. Gain factors exceeded 1.0 at all CNR settings and were largest in the lowest-CNR regimes, with CNR ratios up to approximately 30-fold and SNR ratios up to approximately 6-fold in lowest-CNR conditions.

The method markedly stabilized LA Scar % estimates across CNR degradations. For native-scar phantoms (4.3±1.4% Scar), the spectral reconstruction maintained near-zero bias at mild degradation (0.8±1.9% at 10% degradation; 1.2±2.8% at 20% degradation) and showed substantially smaller underestimation at higher degradation (−3.1±8.2%, −14.3±14.5%, and −26.3±23.0% at 70%, 80%, and 90% degradation, respectively).

In contrast, bright-blood LGE already underestimated Scar % by −19.4±1.9% and −26.5±16.8% at 10% and 20% degradation, worsening to −53.9±24.6%, −66.6±25.1%, and −84.5±17.3% at 70%, 80%, and 90% degradation. Notably, bright-blood bias at only 20% degradation (−26.5±16.8%) was comparable in magnitude to the spectral reconstruction error at 90% degradation (−26.3±23.0%).

Similar behavior was observed in the 10%, 20%, and 30% scar-cloned phantoms. At 70% degradation, the spectral reconstruction errors were only −3.7±5.0% to −4.5±4.4%, compared with bright-blood errors of −37.0±22.0% to −41.3±22.5%.

In the 60 post-ablation 3D LA LGE scans, the spectral reconstruction method consistently improved quantitative image quality metrics compared with bright-blood imaging when analyzed using identical LA segmentations and ROIs.

LA scar-pool CNR increased approximately 6.8-fold from 20.0 to 135.9 (p<0.001). SNR increased approximately 2.8-fold from 70.6 to 200.6 (p<0.001). Effective CNR increased approximately 3.4-fold from 0.22 to 0.75 (p<0.001).

Using the same blood-pool-based threshold (μₚₒₒₗ+3.3σₚₒₒₗ) for both reconstructions, LA Scar % was significantly higher with the spectral reconstruction than with bright-blood (9.75% vs 3.9%, p<0.001). This direction and magnitude aligned with the phantom experiments, where bright-blood systematically underestimated true Scar % as CNR decreased, whereas the spectral reconstruction reduced this underestimation while improving CNR and eCNR.

### Example Computer System

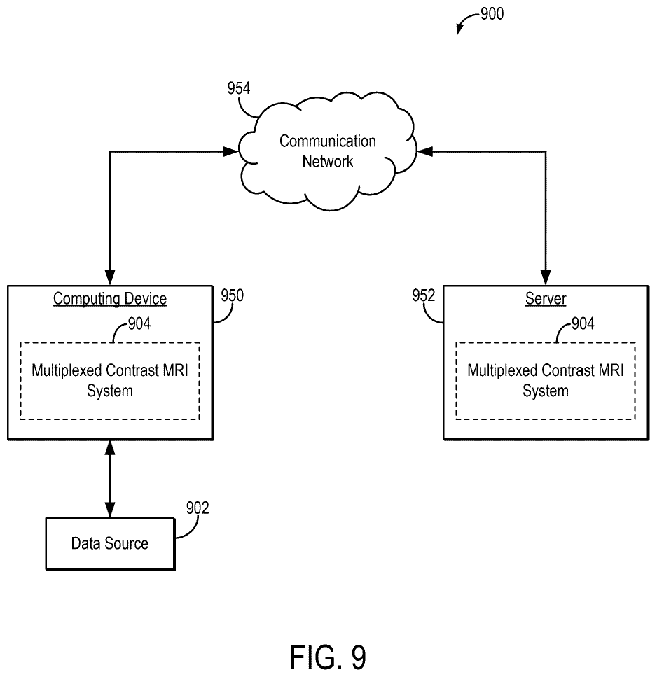

FIG. 9 shows an example of a system 900 for generating images with different contrast weighting using multiplexed contrast MRI techniques in accordance with some embodiments described in the present disclosure. As shown in FIG. 9, a computing device 950 can receive one or more types of data (e.g., magnetic resonance image data) from data source 902. In some embodiments, computing device 950 can execute at least a portion of a multiplexed contrast MRI system 904 to generate images with different contrast weightings from data received from the data source 902.

Additionally or alternatively, in some embodiments, the computing device 950 can communicate information about data received from the data source 902 to a server 952 over a communication network 954, which can execute at least a portion of the multiplexed contrast MRI system 904. In such embodiments, the server 952 can return information to the computing device 950 (and/or any other suitable computing device) indicative of an output of the multiplexed contrast MRI system 904.

In some embodiments, computing device 950 and/or server 952 can be any suitable computing device or combination of devices, such as a desktop computer, a laptop computer, a smartphone, a tablet computer, a wearable computer, a server computer, a virtual machine being executed by a physical computing device, and so on. The computing device 950 and/or server 952 can also reconstruct images from the data.

The system 900 can be configured for interventional MRI applications, operating either on-console (integrated with the MRI system, such as with operating workstation 102) or as a standalone system.

In interventional MRI implementations, the multiplexed contrast MRI system 904 enables retrospective, self-calibrated reconstructions of MRI contrasts without requiring additional scans. This capability increases CNR and SNR while improving contrast separability from navigation scans, thereby supporting procedural guidance, patient safety monitoring, and efficacy assessment before, during, and after therapeutic interventions. The interventional MRI applications of the system 900 can include uses in various clinical tasks. In cardiac ablation procedures, the system 900 can enhance visualization of ablation injury and scar tissue in the left atrium and left ventricle for treatment of atrial fibrillation and ventricular arrhythmias. For tumor ablation procedures, the system 900 can improve delineation of ablation margins in liver, kidney, and prostate interventions. In neurosurgical applications, the system 900 can enhance identification of residual tumor boundaries, such as in glioma resection workflows, to support assessment of surgical completeness. For peripheral vascular interventions, the system 900 can provide improved vessel wall and plaque visualization to guide catheter-based procedures and assess treatment outcomes. In each of these applications, the system 900 can operate on-console during the procedure or as a standalone system for pre-procedural planning and post-procedural evaluation.

In pre-procedural applications, the system 900 can generate images with enhanced contrast weightings from diagnostic scans to support treatment planning, target identification, and procedural approach determination. During intra-procedural use, the multiplexed contrast MRI system 904 can process navigation scans in real-time or near-real-time to provide enhanced visualization for procedural guidance and safety monitoring. In post-procedural applications, the system 900 can assess therapeutic efficacy by generating images that enhance visibility of treatment effects, tissue changes, and procedural outcomes.

In some embodiments, data source 902 can be any suitable source of data (e.g., measurement data, images reconstructed from measurement data, processed image data), such as an MRI system, another computing device (e.g., a server storing measurement data, images reconstructed from measurement data, processed image data), and so on. In some embodiments, data source 902 can be local to computing device 950. For example, data source 902 can be incorporated with computing device 950 (e.g., computing device 950 can be configured as part of a device for measuring, recording, estimating, acquiring, or otherwise collecting or storing data). As another example, data source 902 can be connected to computing device 950 by a cable, a direct wireless link, and so on. Additionally or alternatively, in some embodiments, data source 902 can be located locally and/or remotely from computing device 950, and can communicate data to computing device 950 (and/or server 952) via a communication network (e.g., communication network 954).

In some embodiments, communication network 954 can be any suitable communication network or combination of communication networks. For example, communication network 954 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 954 can be a local area network, a wide area network, a public network (e.g., the Internet), a private or semi-private network (e.g., a corporate or university intranet), any other suitable type of network, or any suitable combination of networks. Communications links shown in FIG. 9 can each be any suitable communications link or combination of communications links, such as wired links, fiber optic links, Wi-Fi links, Bluetooth links, cellular links, and so on.

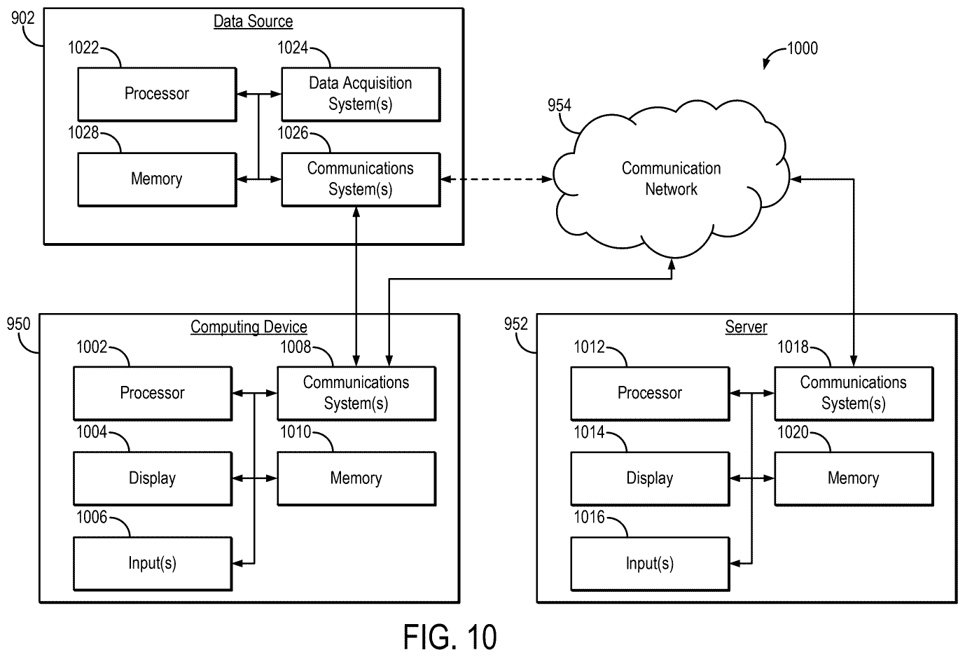

Referring now to FIG. 10, an example of hardware 1000 that can be used to implement data source 902, computing device 950, and server 952 in accordance with some embodiments of the systems and methods described in the present disclosure is shown.

As shown in FIG. 10, in some embodiments, computing device 950 can include a processor 1002, a display 1004, one or more inputs 1006, one or more communication systems 1008, and/or memory 1010. In some embodiments, processor 1002 can be any suitable hardware processor or combination of processors, such as a central processing unit (“CPU”), a graphics processing unit (“GPU”), and so on. In some embodiments, display 1004 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 1006 can include any suitable input devices and/or sensors that can be used to receive user input, such as a keyboard, a mouse, a touchscreen, a microphone, and so on.

In some embodiments, communications systems 1008 can include any suitable hardware, firmware, and/or software for communicating information over communication network 954 and/or any other suitable communication networks. For example, communications systems 1008 can include one or more transceivers, one or more communication chips and/or chip sets, and so on. In a more particular example, communications systems 1008 can include hardware, firmware, and/or software that can be used to establish a Wi-Fi connection, a Bluetooth connection, a cellular connection, an Ethernet connection, and so on.

In some embodiments, memory 1010 can include any suitable storage device or devices that can be used to store instructions, values, data, or the like, that can be used, for example, by processor 1002 to present content using display 1004, to communicate with server 952 via communications system(s) 1008, and so on. Memory 1010 can include any suitable volatile memory, non-volatile memory, storage, or any suitable combination thereof. For example, memory 1010 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 1010 can have encoded thereon, or otherwise stored therein, a computer program for controlling operation of computing device 950. In such embodiments, processor 1002 can execute at least a portion of the computer program to present content (e.g., images, user interfaces, graphics, tables), receive content from server 952, transmit information to server 952, and so on. For example, the processor 1002 and the memory 1010 can be configured to perform the methods described herein (e.g., the method of FIG. 5).

In some embodiments, server 952 can include a processor 1012, a display 1014, one or more inputs 1016, one or more communications systems 1018, and/or memory 1020. In some embodiments, processor 1012 can be any suitable hardware processor or combination of processors, such as a CPU, a GPU, and so on. In some embodiments, display 1014 can include any suitable display devices, such as an LCD screen, LED display, OLED display, electrophoretic display, a computer monitor, a touchscreen, a television, and so on. In some embodiments, inputs 1016 can include any suitable input devices and/or sensors that can be used to receive user input, such as a keyboard, a mouse, a touchscreen, a microphone, and so on.

In some embodiments, communications systems 1018 can include any suitable hardware, firmware, and/or software for communicating information over communication network 954 and/or any other suitable communication networks. For example, communications systems 1018 can include one or more transceivers, one or more communication chips and/or chip sets, and so on. In a more particular example, communications systems 1018 can include hardware, firmware, and/or software that can be used to establish a Wi-Fi connection, a Bluetooth connection, a cellular connection, an Ethernet connection, and so on.

In some embodiments, memory 1020 can include any suitable storage device or devices that can be used to store instructions, values, data, or the like, that can be used, for example, by processor 1012 to present content using display 1014, to communicate with one or more computing devices 950, and so on. Memory 1020 can include any suitable volatile memory, non-volatile memory, storage, or any suitable combination thereof. For example, memory 1020 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 1020 can have encoded thereon a server program for controlling operation of server 952. In such embodiments, processor 1012 can execute at least a portion of the server program to transmit information and/or content (e.g., data, images, a user interface) to one or more computing devices 950, receive information and/or content from one or more computing devices 950, receive instructions from one or more devices (e.g., a personal computer, a laptop computer, a tablet computer, a smartphone), and so on.

In some embodiments, the server 952 is configured to perform the methods described in the present disclosure. For example, the processor 1012 and memory 1020 can be configured to perform the methods described herein (e.g., the method of FIG. 5).

In some embodiments, data source 902 can include a processor 1022, one or more data acquisition systems 1024, one or more communications systems 1026, and/or memory 1028. In some embodiments, processor 1022 can be any suitable hardware processor or combination of processors, such as a CPU, a GPU, and so on. In some embodiments, the one or more data acquisition systems 1024 are generally configured to acquire data, images, or both, and can include an MRI system. Additionally or alternatively, in some embodiments, the one or more data acquisition systems 1024 can include any suitable hardware, firmware, and/or software for coupling to and/or controlling operations of an MRI system. In some embodiments, one or more portions of the data acquisition system(s) 1024 can be removable and/or replaceable.

Note that, although not shown, data source 902 can include any suitable inputs and/or outputs. For example, data source 902 can include input devices and/or sensors that can be used to receive user input, such as a keyboard, a mouse, a touchscreen, a microphone, a trackpad, a trackball, and so on. As another example, data source 902 can include any suitable display devices, such as an LCD screen, an LED display, an OLED display, an electrophoretic display, a computer monitor, a touchscreen, a television, etc., one or more speakers, and so on.

In some embodiments, communications systems 1026 can include any suitable hardware, firmware, and/or software for communicating information to computing device 950 (and, in some embodiments, over communication network 954 and/or any other suitable communication networks). For example, communications systems 1026 can include one or more transceivers, one or more communication chips and/or chip sets, and so on. In a more particular example, communications systems 1026 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 1028 can include any suitable storage device or devices that can be used to store instructions, values, data, or the like, that can be used, for example, by processor 1022 to control the one or more data acquisition systems 1024, and/or receive data from the one or more data acquisition systems 1024; to generate images from data; present content (e.g., data, images, a user interface) using a display; communicate with one or more computing devices 950; and so on. Memory 1028 can include any suitable volatile memory, non-volatile memory, storage, or any suitable combination thereof. For example, memory 1028 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 1028 can have encoded thereon, or otherwise stored therein, a program for controlling operation of data source 902. In such embodiments, processor 1022 can execute at least a portion of the program to generate images, transmit information and/or content (e.g., data, images, a user interface) to one or more computing devices 950, receive information and/or content from one or more computing devices 950, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As used herein in the context of computer implementation, unless otherwise specified or limited, the terms “component,” “system,” “module,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

### Example MRI System

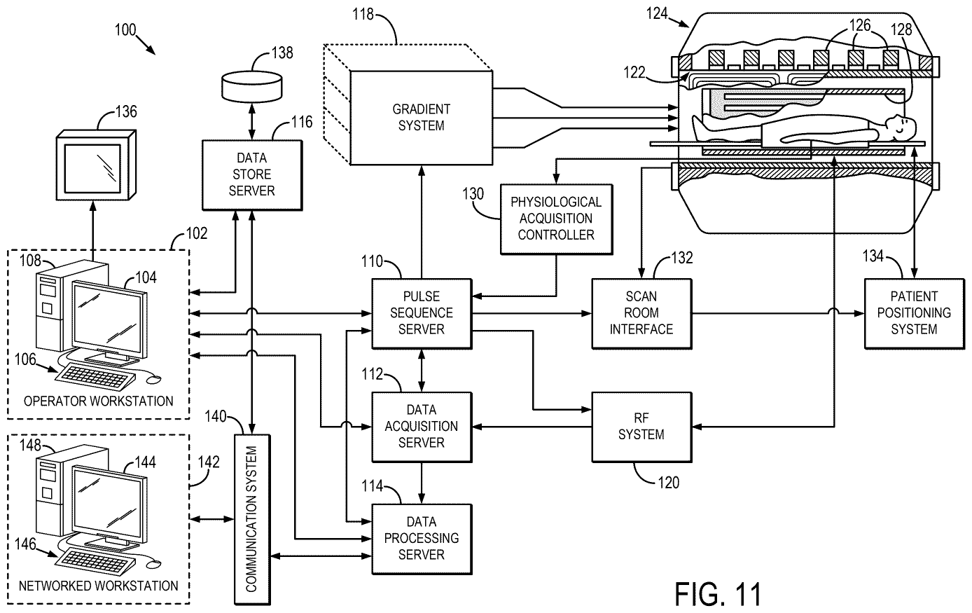

Referring particularly now to FIG. 11, an example of an MRI system 100 that can implement the methods described here is illustrated. The MRI system 100 includes an operator workstation 102 that may include a display 104, one or more input devices 106 (e.g., a keyboard, a mouse), and a processor 108. The processor 108 may include a commercially available programmable machine running a commercially available operating system. The operator workstation 102 provides an operator interface that facilitates entering scan parameters into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include wired or wireless network connections.

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which then excites gradient coils in an assembly 122 to produce the magnetic field gradients G_{y}, G_{y}, and G_{z} that are used for spatially encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil to perform the prescribed magnetic resonance pulse sequence. Responsive magnetic resonance signals detected by the RF coil 128, or a separate local coil, are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. An RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 110 may receive patient data from a physiological acquisition controller 130. By way of example, the physiological acquisition controller 130 may receive signals from a number of different sensors connected to the patient, including electrocardiograph (“ECG”) signals from electrodes, or respiratory signals from a respiratory bellows or other respiratory monitoring devices. These signals may be used by the pulse sequence server 110 to synchronize, or “gate,” the performance of the scan with the subject's heart beat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, so that data is not lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and processes it in real-time to produce information that is used to control the scan.

The data processing server 114 receives magnetic resonance data from the data acquisition server 112 and processes the magnetic resonance data in accordance with instructions provided by the operator workstation 102. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache, from which they may be output to operator display 102 or a display 136. Batch mode images or selected real time images may be stored in a host database on disc storage 138. When such images have been reconstructed and transferred to storage, the data processing server 114 may notify the data store server 116 on the operator workstation 102. The operator workstation 102 may be used by an operator to archive the images, produce films, or send the images via a network to other facilities.

The MRI system 100 may also include one or more networked workstations 142. For example, a networked workstation 142 may include a display 144, one or more input devices 146 (e.g., a keyboard, a mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142.

The present disclosure has described one or more preferred embodiments, and it should be appreciated that many equivalents, alternatives, variations, and modifications, aside from those expressly stated, are possible and within the scope of the invention.

1. A method for multiplexed contrast magnetic resonance imaging (MRI), the method comprising:
accessing a first image acquired with an MRI system from a subject, wherein the first image has a first contrast weighting;
selecting a region-of-interest in the first image as a calibration region;
generating an input image spectral profile based on comparing voxels in the first image and voxels in the calibration region;
generating a calibration spectral profile based on comparing voxels in the calibration region with other voxels in the calibration region;
generating spectrally resolved images by binning the first image based on histogram values determined based on the input image spectral profile;
generating cumulative maps by extracting image intensity values from the spectrally resolved images corresponding to different spectral ranges determined from the calibration spectral profile; and
generating a second image by selectively combining the cumulative maps, wherein the second image has a second contrast weighting that is different than the first contrast weighting.

2. The method of claim 1, wherein the second contrast weighting differs from the first contrast weighting by suppressing image intensity values of tissues contained in the calibration region.

3. The method of claim 2, wherein the cumulative maps include a cumulative map associated with the tissues contained in the calibration region and at least one cumulative map associated with other image data in the input image.

4. The method of claim 3, wherein selectively combining the cumulative maps includes subtracting the cumulative map associated with the tissues contained in the calibration region from the at least one cumulative map associated with other image data in the input image.

5. The method of claim 1, wherein the second contrast weighting differs from the first contrast weighting by amplifying image intensity values relative to tissues contained in the calibration region.

6. The method of claim 1, wherein selectively combining the cumulative maps includes weighting at least one of the cumulative maps to amplify the image intensity values relative to tissues contained in the calibration region.

7. The method of claim 1, wherein the input image spectral profile is generated by computing cross-disparity values between voxels in the first image and voxels in the calibration region.

8. The method of claim 7, wherein the input image spectral profile comprises one of a probability density function of the cross-disparity values or a histogram of the cross-disparity values.

9. The method of claim 1, wherein the calibration spectral profile is generated by computing auto-self-disparity values between voxels in the calibration region and other voxels in the calibration region.

10. The method of claim 9, wherein the calibration spectral profile comprises a probability density function of the auto-self-disparity values.

11. The method of claim 1, wherein generating the generating the spectrally resolved images comprises:
defining bin edges from the input image spectral profile;
retracing image indices within bin ranges defined by the bin edges;
extracting unique indices from the retraced image indices as nonduplicated image indices;
constructing a histogram of the unique indices; and
binning the first image based on histogram values of the histogram of the unique indices.

12. The method of claim 11, wherein the first image is based on normalized histogram values of the histogram of the unique indices.

13. The method of claim 1, wherein generating the cumulative maps comprises:
determining a plurality of calibration points based on the calibration spectral profile;
defining spectral ranges using the plurality of calibration points; and
assigning image intensity values from the spectrally resolved images to different cumulative maps based on which spectral ranges are associated with each cumulative map.

14. The method of claim 13, wherein the plurality of calibration points comprises a first calibration point and a second calibration point.

15. The method of claim 14, wherein the first calibration point is selected as a first bin index at which the calibration spectral profile is greater than zero.

16. The method of claim 14, wherein the second calibration point is selected as a first bin index at which a cumulative density function of the calibration profile equals a threshold value.

17. The method of claim 16, wherein the threshold value is one.

18. The method of claim 14, wherein the cumulative maps comprise a first cumulative map associated with spectrally resolved image data below the first calibration point, a second cumulative map associated with spectrally resolved image data between the first and second calibration points, and a third cumulative map associated with spectrally resolved image data above the second calibration point.

19. The method of claim 18, wherein the second cumulative map corresponds to image intensity values in the spectrally resolved images that are associated with tissues contained in the calibration region.

20. The method of claim 19, wherein selectively combining the cumulative maps comprises subtracting the second cumulative map from a sum of the first and third cumulative maps.

21. The method of claim 1, wherein selectively combining the cumulative maps includes computing a difference between at least two cumulative maps.

22. The method of claim 1, wherein selectively combining the cumulative maps includes computing a sum between at least two cumulative maps.

23. The method of claim 1, wherein selectively combining the cumulative maps includes combining at least two cumulative maps according to a function.

24. The method of claim 1, wherein the calibration region is selected as a region containing blood pool signals.

25. The method of claim 24, wherein the first image comprises a bright-blood image and the second image comprises a dark-blood image.

26. A method for multiplexed contrast magnetic resonance imaging (MRI), the method comprising:
accessing a first image acquired with an MRI system from a subject, wherein the first image has a first contrast weighting;
selecting a region-of-interest in the first image as a calibration region;
generating an input image spectral profile based on comparing voxels in the first image and voxels in the calibration region;
generating a calibration spectral profile based on comparing voxels in the calibration region with other voxels in the calibration region;
generating spectrally resolved images by binning the first image based on histogram values determined based on the input image spectral profile; and
generating, from the spectrally resolved images, a second image having a second contrast weighting that is different than the first contrast weighting.

27. The method of claim 26, wherein generating the second image comprises outputting one of the spectrally resolved images as the second image.

28. The method of claim 26, wherein generating the second image comprises selectively combining a plurality of the spectrally resolved images to form the second image.

29. The method of claim 26, wherein generating the second image comprises generating cumulative maps by extracting image intensity values from the spectrally resolved images corresponding to different spectral ranges determined from the calibration spectral profile and selectively combining a plurality of the cumulative maps to form the second image.
